(19) United States
(12) Patent Application Publication
(10) Pub. No.: US 2024/0072190 A1
(43) Pub. Date: Feb. 29, 2024

(54) A SOLAR CELL

(71) Applicant: REC SOLAR PTE. LTD., Singapore (SG)

(72) Inventors: Muzhi TANG, Singapore (SG); Priyadharsini KARUPPUSWAMY, Singapore (SG); Shu Yunn CHONG, Singapore (SG); Kenta NAKAYASHIKI, Singapore (SG)

(73) Assignee: REC SOLAR PTE. LTD., Singapore (SG)

(21) Appl. No.: 18/259,818

(22) PCT Filed: Dec. 20, 2021
(86) PCT No.: PCT/EP2021/086827

§ 371 Date: Jun. 29, 2023

(30) Foreign Application Priority Data
Dec. 30, 2020 (GB) GB 2020732.0

(51) Int. Cl. H01L 31/077; H01L 31/0475; H01L 31/076; H01L 31/18

(52) U.S. Cl. CPC H01L 31/077; H01L 31/0475; H01L 31/076; H01L 31/1816

(57) ABSTRACT

A solar cell comprising a silicon substrate and a layered structure arranged on a surface of the silicon substrate, the layered structure comprising; a first layer comprising a percentage of crystalline material arranged within an amorphous matrix, the first layer being arranged on the surface of the silicon substrate; a second layer comprising a percentage of crystalline material arranged within an amorphous matrix, the second layer being interposed between the first layer and the surface of the silicon substrate; wherein the percentage of crystalline material in the first layer is greater than the percentage of crystalline material in the second layer.

### FIELD OF THE DISCLOSURE

The present disclosure relates to solar cells and methods for forming the same.

### BACKGROUND

Solar modules for providing electrical energy from sunlight comprise an array of solar/photovoltaic cells, each comprising a multi-layer semiconductor structure arranged between one or more front and back electrodes.

The substrate typically forms a p-n junction with an emitter layer (i.e. one of the substrate and the emitter layers being an n-type material and the other being a p-type material), which facilitates the generation of an electric current in response to light incident on the solar cell.

The solar cell can also include an accumulation layer, arranged on an opposite portion of the substrate to the emitter layer. The accumulation layer forms a highly doped layer arranged to extract charge carriers from the substrate. The accumulation layer may be either a front surface field (FSF) or a back surface field layer (BSF), depending on whether it's arranged at the front or back side of the substrate. For example, if the accumulation layer is arranged on the back side of the substrate (i.e. to define a BSF) then the emitter is arranged on the front side of the substrate to define a front junction solar cell.

Accordingly, one of the emitter and accumulation layers is electrically connected to a front electrode, and the other of the emitter and accumulation layers is connected to a back electrode. The emitter and accumulation layers are typically formed of amorphous silicon (a-Si) whereas the substrate is formed of crystalline silicon (c-Si) so as to define a heterojunction technology (HJT) solar cell.

To maximise the efficiency of such solar cells, it is important to minimise the number of surface defects which can form at the interfaces between the different layers of the multilayer structure. This is because surface defects can be detrimental to the operation of the solar cell. For example, charge carriers recombine at defect sites located near to the p-n junction, instead of being collected by the electrodes. The recombination of the charge carriers is one of the main reasons for decreased photovoltaic conversion efficiency of a solar cell.

One way in which the negative effects of surface defects can be reduced is by passivation of the interfaces which form within the solar cell. Typically, this is achieved by forming a layer of intrinsic (i.e. un-doped) semiconductor material between the substrate and each of the emitter and accumulation layers. The presence of this intrinsic layer decreases the recombination of charge carriers at the surface of the substrate, and thereby improves the performance of the solar cell.

The presence of the intrinsic layers, while beneficial, also results in the formation of a further interface within the solar cell, e.g. between the intrinsic layer and the overlying emitter layer, which provides another site for impurities to accumulate, and thereby increasing charge carrier recombination. If the intrinsic layer is too thick, it can also increase the resistivity of the solar cell by inhibiting the transportation of charge carriers towards the electrodes.

Additionally, the interface between the intrinsic and doped semiconductor layers can result in an abrupt change in conductivity, and/or variations in band gap. The resulting band bending at the interface can lead to a high density of interface states, which is another source of charge carrier recombination.

Accordingly, there is a need to reduce the prevalence of charge carrier recombination within such solar cells, whilst also improving the charge carrier transport properties.

### SUMMARY

According to a first aspect there is provided a solar cell comprising a substrate (e.g. a silicon substrate) and a layered structure arranged on a surface of the substrate, the layered structure comprising;
a first layer comprising a percentage of crystalline material arranged within an amorphous matrix, the first layer being arranged on the surface of the substrate;
a second layer comprising a percentage of crystalline material arranged within an amorphous matrix, the second layer being interposed between the first layer and the surface of the substrate;
wherein the percentage of crystalline material in the first layer is greater than the percentage of crystalline material in the second layer.

The inclusion of a higher concentration of crystalline material in the first layer reduces the resistivity of the layered structure away from the substrate. As such, the contact resistivity between the layered structure and an electrode of the solar cell may be reduced which thereby increases the fill factor of the solar cell. Conversely, the higher concentration of amorphous material in the second layer leads to increased light absorption towards the surface of the substrate, thereby increasing the short circuit current (lsc) and hence the performance of the solar cell.

Optional features will now be set out. These are applicable singly or in any combination with any aspect.

It will be understood that when an element such as a layer, film, region, or substrate is referred to as being “on”, “adjacent” or “opposite” to an element, it can be “directly on”, “directly adjacent” or “directly opposite” to that further element; alternatively, there may be one or more intervening elements present. In contrast, when an element is referred to as being “directly on”, “directly adjacent” or “directly opposite” another element, there are no intervening elements present.

The first layer may be arranged directly on the second layer. In this way, there may be a defined step change in the concentration of crystalline material at the interface between the first and second layers. As such, there may be no substantially amorphous layers arranged between the first and second layers.

The layered structure may be defined herein as having a first and a second layer, however it will be appreciated that the layered structure may also, in certain embodiments, comprise two or more layers, e.g. a plurality of layers. It is to be understood that the layers of the layered structure may be discrete layers with defined step-changes in the percentage of crystalline material between adjacent layers. As such, clear boundaries may be present between these discrete layers, wherein each boundary is defined by a step-change in the percentage of crystalline material.

The layers may be configured such that at least one, or each, of the layers of the layered structure may have a substantially graded structural composition when measured across their depth(s). In this way, the structural composition of the at least one, or each of the layers may vary such that, when moving away from the substrate the concentration of crystalline material increases gradually. The layers may be configured such that the percentage of crystallinity at any depth of the first layer will be greater than the percentage of crystallinity at any depth of the second layer so as to provide a relative change in the percentage of crystallinity across the depth of the layered structure.

Additionally, it is to be understood that the layers of the layered structure may comprise a plurality of layers, each with a continuously graded structure such that there is no defined step-change in the percentage of crystalline material across the layered structure. As such, no clear boundaries (as described above) may be present between the continuously graded layers and, instead, the percentage of crystalline material may vary gradually through a thickness of the layered structure. Furthermore, it is also to be understood that in some embodiments, one or more layers of the layered structure may be discrete layers and one or more other layers of the same layered structure may be continuously graded layers.

It will be understood that a crystalline material is defined as a material which exhibits long range order in at least one direction. Accordingly, such crystalline materials are comprised of atoms arranged in a unit cell which repeats over a large distance, e.g. the constituent atoms exhibit translational periodicity.

By contrast, amorphous materials are characterised by having a short-range order, in which the constituent atoms are bonded in disordered, random spatial positions, because of factors that do not allow the formation of a regular arrangement.

A monocrystalline material is defined as a material which consists solely of crystalline material having a single continuous crystal lattice, e.g. with no internal grain boundaries. Accordingly, such monocrystalline materials consist solely of crystalline material with substantially no amorphous material present. A polycrystalline material (aka multi-crystalline material) is comprised from a plurality of crystallites, or grains. Each of the crystallites exhibits long-range ordering of the atoms in the unit cells which define the crystal structure. Accordingly, such polycrystalline materials (and multi-crystalline materials) consist solely of crystalline material with substantially no amorphous material present. Both monocrystalline and polycrystalline materials exhibit long-range ordering in substantially all directions.

The substrate may be comprised of crystalline silicon (c-Si). The crystalline silicon substrate may comprise a continuous crystal structure, e.g. monocrystalline silicon. Alternatively, the substrate may comprise one or more grains of a continuous crystal structure, e.g. polycrystalline (or multi-crystalline) silicon.

With regards to the first and second layers of the layered structure, it will be understood that the crystalline material within each of these layers is defined as having a para-crystalline structure which exhibits a degree of short and/or medium range ordering in its crystal structure, but which lacks long-range ordering in at least one direction. Accordingly, each of the first and second layers of the layered structure at least partially comprise amorphous material in which the crystalline material is arranged, or embedded. This is in contrast to monocrystalline or polycrystalline materials which consist solely of crystalline material.

The material within each of the first and second layers may be configured to include one or more crystalline regions arranged, or embedded, within an amorphous matrix. For example, the crystalline material may be, or include, one or more discrete crystalline particles arranged within the matrix of amorphous material. Each of the crystalline regions may exhibit a degree of long-range order in its crystal structure. In view of the foregoing, it will be appreciated that each of the first and second layers (together with the third layer described below) may be configured such that they are not formed of monocrystalline, and/or polycrystalline (aka multi-crystalline), materials.

Each of first and second layers may be configured with a width, a length and a depth. Each such layer may be configured such that its width and length are both substantially greater than its depth. The width and length of the layers may be measured in perpendicular directions aligned with the plane of the surface of the substrate, and the depth may be measured in a direction which is perpendicular to the plane of the surface of the substrate. The crystalline material (e.g. the plurality of crystalline regions) may be dispersed evenly across the depth of the layers.

The crystalline regions, or particles, may be configured such that they substantially all have a size that is of the order of nanometres (i.e. substantially all of the crystalline regions have at least one dimension measuring less than 1000 nanometers). As such, at least one, or each, of the first, second and third layers may be formed of a nanocrystalline material. In an illustrative embodiment, substantially all of the crystalline regions, or particles, may be configured such that at least one dimension is approximately less than 15 nm, alternatively approximately less than 10 nm.

According to an exemplary arrangement, substantially all of the crystalline regions, or particles, may be configured such that at least one dimension may be approximately less than 5 nm. According to a further exemplary arrangement, substantially all of the plurality of crystalline regions, or particles, may be configured such that a largest dimension is less than 5 nm. According to a further exemplary arrangement, substantially all of the crystalline regions, or particles, may be configured such that substantially all of their dimensions measure approximately less than 5 nm.

As described above, the first layer is configured with a greater percentage, or concentration, of crystalline material than the second layer. It will be appreciated that the concentration of crystalline material within each of the layers may be defined as a mass or volume fraction of the respective layer.

According to an illustrative embodiment, the percentage of crystalline material in the first layer may be between 75% and 100%, alternatively 70% to 100%. In one embodiment, the percentage of crystalline material in the first layer may be a constant value. In another embodiment, the percentage of crystalline material in the first layer may vary, wherein the percentage crystallinity increases in a direction away from the substrate.

The percentage of crystalline material in the second layer may be between 50% and 75%, alternatively between 50% and 70%. In one embodiment, the percentage of crystalline material in the second layer may be a constant value. In another embodiment, the percentage of crystalline material in the second layer may vary, wherein the percentage crystallinity increases in a direction away from the substrate.

In an exemplary embodiment, the first layer may have a percentage of crystalline material which varies between 75% and 100% and the second layer has a percentage of crystalline material which varies between 50% and 75%, wherein the percentage crystallinity increases in both the first and second layers in a direction moving away from the substrate. According to this arrangement, the percentage of crystallinity of the first and second layers is graded across the interface between the layers such that the crystallinity of the layered structure is continuously graded across its depth.

The layered structure may comprise a third layer comprising a percentage of crystalline material arranged within an amorphous matrix. The third layer may be interposed between the second layer and the surface of the substrate. The layered structure may further comprise a passivation layer which may be interposed between the third layer and the surface of the substrate. In this way, the third layer may be directly interposed between the second layer and the passivation layer.

The passivation layer may be formed of amorphous material which may be configured to passivate the substrate surface upon which the layered structure is arranged. According to an illustrative embodiment, the passivation layer may be formed solely from amorphous material.

The third layer of the layered structure may be configured in a similar manner to that of the first and second layers. As such, the crystalline material within the third layer may be defined as having a para-crystalline structure which exhibits a degree of short and/or medium range ordering in its crystal structure, but which lacks long-range ordering in at least one direction. The third layer may at least partially comprise amorphous material in which the crystalline material is arranged, or embedded, such that it does not constitute either a monocrystalline or polycrystalline material. Furthermore, the material within the third layer may be configured to include one or more crystalline regions arranged, or embedded, within an amorphous matrix, as described in the preceding paragraphs.

The percentage of crystalline material in the third layer may be less than, or substantially the same as, the percentage of crystalline material in the second layer. By configuring the third layer with a smaller percentage of crystalline material, it increases the relative proportion of amorphous material present in the layer, which means that the thickness of the passivation layer can be reduced whilst maintaining the passivation of the substrate surface. Reducing the thickness of the passivation layer can further reduce the resistivity of the layered structure, and thereby increase the fill factor of the solar cell. The presence of more amorphous material in the third layer also increases photon absorption near to the substrate, thereby increasing the performance of the solar cell. By providing the third layer with a lower percentage of crystalline material than the second layer, this creates a gradual change in in the crystallinity (e.g., through the layered structure) which reduces the difference in the resistivity between adjacent layers, which may otherwise restrict the flow of charge carriers (e.g., from the substrate to an electrode of the solar cell).

According to an exemplary arrangement, at least one of the first and second layers may be configured with a compositional gradient across their depth(s). The third layer may be compositionally graded across its depth, from substantially amorphous at the interface with the passivation layer to at least partially crystalline at the interface with the second layer. The second layer may be compositionally graded across its depth from a lower crystallinity at the interface with the third layer to a higher crystallinity at its interface with the first layer. The first layer may be compositionally graded across its depth from a lower crystallinity at the interface with the second layer to a higher crystallinity at the interface with the electrode.

According to an exemplary arrangement, the solar cell may comprise an electrode which is arranged on a surface of the layered structure opposite from a surface which forms an interface with the substrate (e.g. such that the layered structure may be interposed between the substrate and the electrode). A transparent conductive oxide (TCO) may be interposed between the electrode and the layered structure such that it is positioned in direct contact with the first layer. The transparent conductive oxide and the electrode may each be configured to extract charge carriers from the layered structure, and in particular the first layer. In this situation, by configuring the first layer with a greater concentration of crystalline material it creates a better electrical (e.g. ohmic) contact with the transparent conductive oxide layer to increase the extraction of charge carriers from the layered structure, and thereby increases the fill factor of the solar cell.

Each layer of the layered structure may be formed of a material having a prescribed chemical composition. Each one of the layers may be deposited (or e.g. diffused or implanted) on to the substrate. The amorphous matrix material may be formed of the same material, e.g. a material having the same chemical composition, as the region(s) of crystalline material. Alternatively, the region(s) of crystalline material may be formed of a different material to that of the amorphous matrix material.

The first layer may be formed of a first material which comprises at least one of silicon, silicon sub-oxide (SiOx) and silicon carbide (SiC). The second layer may be formed of a second material which comprises at least one of silicon, silicon sub-oxide (SiOx) and silicon carbide (SiC). The third layer may be formed of a third material which comprises at least one of silicon, silicon sub-oxide (SiOx) and silicon carbide (SiC). In each of the layers, above, the silicon, silicon sub-oxide (SiOx) and silicon carbide (SiC) may be present in an amorphous and crystalline form.

It will be appreciated that silicon sub-oxide defines a class of silicon oxides wherein the electropositive element (i.e. silicon) is in excess relative to the normal oxides (e.g. SiO2). Silicon sub-oxide can be deposited by vapour deposition processing at relative low temperatures (e.g. less than 300° C.), which prevents any damage to the underlying amorphous silicon.

The use of silicon sub-oxide and/or silicon carbide increases the conductivity and the transparency of the layers compared with an equivalent layer formed of purely silicon.

The passivation layer may be formed of amorphous silicon (a-Si). Alternatively, the passivation may be formed of at least one of amorphous silicon sub-oxide (SiOx) and amorphous silicon carbide (SiC).

According to an exemplary arrangement the layered structure may be arranged on a surface of the substrate upon which light from a radiative source (e.g. the sun) is incident in use (e.g. a front surface of the substrate which is configured to face a radiative source, when the solar cell is in use). In this case, each of the first, second and third layers and the passivation layer may be formed of at least one of silicon sub-oxide (SiOx) and silicon carbide (SiC). It is noted that a back surface of the substrate is understood to be opposite the front surface of the substrate, and in use incident light hits the rear surface after it hits the front surface.

The inclusion of silicon sub-oxide and/or silicon carbide helps to increase the transparency of the layered structure compared to an equivalent structure formed of silicon. The different in absorption can be attributed to the different bandgaps of these materials. Furthermore, by reducing the light absorption of the first layer, the SiOx/SiC also increases the short circuit current (lsc) and hence the performance of the solar cell. This effect is at least partially attributed to the increased number of photons which are able to pass through the layered structure at the front of the substrate, without being absorbed by it. These unabsorbed photons are more likely to reach the substrate whereupon they can contribute to the number of photogenerated charge carriers produced by the solar cell.

According to an exemplary arrangement in which the layered structure is arranged on a surface of the substrate upon which light is not directly incident (e.g. a back surface of the substrate). In this case, the inclusion of silicon sub-oxide and/or silicon carbide in the first layer may be particularly advantageous because it increases the conductivity of the layer compared to an equivalent layer formed of amorphous silicon.

The silicon sub-oxide and/or silicon carbide material in the first and second layers increases charge carrier transport properties between the layered structure and a corresponding electrode of the solar cell. In particular, the silicon sub-oxide and/or silicon carbide causes band bending at the interface between the first layer and the electrode in order to increase the tunnelling of charge carriers therebetween.

The third layer may be formed of silicon (Si). The silicon may be present in both an amorphous and a crystalline form. The passivation layer may be formed of amorphous silicon. The silicon in the third layer increases the passivation of the substrate compared with silicon sub-oxide and/or silicon carbide. The silicon can also advantageously increase the absorption of photons close to the substrate, which increases the number of photogenerated charge carriers produced by the solar cell.

It will be understood from the foregoing that both the substrate and the layered structure may be formed from one or more semiconductor materials. Each of the semiconductor materials may be configured with a conductivity type which is determined by the inclusion of dopant atoms. In this way, each of the respective semiconductor materials may be doped with atoms having a determined charge, in order to increase the excess charge carriers within the doped bulk material.

Accordingly, at least one of the layers of the layered structure may be configured with a conductivity type determined by the inclusion of dopant atoms. The first layer may comprise a first concentration of dopant atoms. The second layer may comprise a second concentration of dopant atoms which is less than the first concentration of dopant atoms, of the first layer. The third layer may comprise a third concentration of dopant atoms which is less than the second concentration of dopant atoms in the second layer.

The layered structure may be configured such that it comprises two or more step changes in dopant concentration when measured across its depth. The first dopant concentration step change occurs between the third and second layers, whilst the second dopant concentration step change is realised at the interface between the second and third layers. The relatively low dopant concentration in the third layer helps to increase passivation of the surface of the substrate, whilst the sequential and progressive change in dopant concentration creates a gradual reduction in the resistivity across the layered structure, which thereby increases the fill factor of the solar cell.

In an exemplary arrangement where the first layer may be electrically connected to an electrode of the solar cell, then the greater dopant concentration of the first layer (relative to the second and third layers) leads to increased charge carrier transport within, and/or through, the first layer. This then results in an improved electrical connection between the layered structure and the electrode.

In embodiments, the layered structure may comprise a plurality of layers which are configured such that the layered structure comprises a substantially graded structural composition when measured across its depth. In this instance, the dopant concentration of the layered structure may gradually increase moving away from the substrate.

It will be understood that the ionisation state of the dopant atoms may determine the conductivity type of the doped semiconductor material. For example, the semiconductor materials may be positively or negatively doped so as to exhibit a positive conductivity type (p-type) or a negative conductivity (n-type), respectively. Any layer having a determined conductivity type (e.g. p-type or n-type) may be configured to create an electrostatic driving force that drives photogenerated charge carriers (e.g. electrons and holes) towards that layer. For example, a p-type material will attract electrons and repel holes, and an n-type material will attract holes and repel electrons. In some cases, the semiconductor material may not be doped (e.g. such as with the intrinsic passivation layer).

The substrate may be configured with a first conductivity type (for example, n-type) and the layered structure may be configured with a second conductivity type (for example, a p-type) opposite the first conductivity type, and thus forms a p-n junction along with the substrate. According to such an arrangement, the layered structure may define an emitter of the solar cell.

The interface formed between the p-type and n-type materials at the p-n junction causes excess electrons and holes to diffuse to the n-type and p-type materials, respectively. This relative movement of the charge carriers results in the formation a depletion region (e.g. a space charge region) at the p-n junction. A built-in potential difference is formed across the depletion region once a thermal equilibrium condition is reached.

During operation of the solar cell, a plurality of electron-hole pairs produced by light incident on the substrate is separated into electrons and holes by the electric filed created by the built-in potential difference resulting from the p-n junction. Then, the separated electrons move (e.g. tunnel) to the n-type semiconductor, and the separated holes move to the p-type semiconductor. Thus, when the substrate is n-type and the emitter is p-type, the separated holes and electrons move to the emitter and the substrate, respectively. Accordingly, the electrons become majority carriers in the substrate, and the holes become majority carriers in the emitter.

According to an exemplary arrangement, the substrate may be formed from an n-type monocrystalline silicon wafer, which exhibits longer lifetime characteristics compared to a p-type monocrystalline silicon wafer. At least one of the layers of the layered structure may comprise a non-monocrystalline material (e.g. amorphous or nanocrystalline) which is at least partially doped so as to be p-type. Such an arrangement may contribute towards the formation of a heterojunction technology (HJT) type solar cell, which is so defined because it combines two different materials to create a charge separating field at the p-n junction. The passivation layer may be configured with no conductivity type such that it forms an intrinsic layer between the emitter and the substrate.

When the semiconductor material is n-type, it may be configured to contain impurities of a group V element such as phosphor (P), arsenic (As), and antimony (Sb). When the semiconductor material is p-type, it may contain impurities of a group III element such as boron (B), gallium (Ga), and indium (In).

Alternatively, the emitter may be n-type and the substrate may be p-type so as to form a p-n junction therebetween. In this instance, during operation of the solar cell assembly the separated holes and electrons move to the substrate and the emitter, respectively.

According to an alternative exemplary arrangement, the layered structure may be configured with the first conductivity type (e.g. n-type), which is the same as that of the substrate. As such, the layered structure may define an accumulator, of the solar cell, which is configured to selectively screen, or extract, charge carriers from the substrate. In embodiments, the substrate may be formed of an n-type monocrystalline silicon wafer and each of the layers of the layered structure may comprise a non-monocrystalline material which is at least partially doped so as to be n-type. The passivation layer may be configured with no conductivity type, such that it forms an intrinsic layer between the accumulator and the substrate.

As well as being configured with a determined conductivity type, at least one or each of the layers of the layered structure may be configured with a different dopant concentration. The first layer may be configured with a first concentration of dopant atoms which is greater than that of the second and/or third layers. The second layer may be configured with a second concentration of dopant atoms which is less than the first layer and greater than the third layer. The third layer may be configured with a third concentration of dopant atoms which is less than the first and/or second concentration. In this way, the first layer defines a heavily doped layer (p++, n++), the second layer defines an intermediately doped layer (p+, n+) and the third layer defines a lightly doped layer (p, n) of the layered structure.

As described above, each of the doped layers may be configured to create an electrostatic driving force that drives photogenerated charge carriers (e.g. electrons and holes) towards the respective layers. The increased doping concentration of the heavily doped layers creates a stronger electrostatic force leading to increased charge transport moving away from the substrate. For example, a first layer formed of a heavily doped p-type material (i.e. p++) may be configured to apply a greater attractive force to photogenerated charge carriers within the solar cell, compared to second and third layers being formed, respectively, of intermediately and lightly doped p-type materials (i.e. p+ and p).

The dopant concentration of at least one or each of the first, second and third layers may be up to 10%, optionally up to 5%, optionally up to 2% and optionally up to 1%.

In embodiments, the first and second layers may comprise a combined depth of less than 9 nm. The combined depth of the first and second layers may be at least 1 nm. The depth of the first layer may be 2 nm. The depth of the second layer may be 7 nm. The third layer may comprise a depth of less than 5 nm. The depth of the third layer may be less than 4 nm. The depth of the third layer may be at least 1 nm. The depth of third layer may be 2 nm.

According to an illustrative embodiment, the layered structure includes first, second and third layers each comprising progressively lower percentages of crystalline material arranged within an amorphous matrix. It will be appreciated that the layered structure may be configured with one or more additional layers interposed between the third layer and the substrate, e.g. fourth, fifth and/or sixth layers, each with progressively lower, or substantially equal, percentages of crystalline material. Furthermore, each of the additional layers may be configured with progressively lower, or equal, dopant concentrations.

The surface of the substrate may define a surface upon which light from a radiative source is first incident, when the solar cell is in use (i.e. light hits this surface before it hits an opposite surface of the substrate). As such, the surface may define a front (i.e. frontmost) surface of the substrate. According to an alternative arrangement, the surface may be configured such that it is not directly exposed to incident light from a radiative source, when the solar cell is in use (i.e. light hits this surface after it hits an opposite surface of the substrate). Accordingly, the surface may define a back (i.e. rearmost) surface of the substrate. The solar cell may be configured so that the front surface is exposed to incident light and the back surface is exposed to reflected light.

According to an exemplary arrangement, the layered structure may define a front layered structure arranged on a front surface of the substrate such that the first and second layers define first and second front layers, respectively. The solar cell may further comprise a back layered structure arranged on a back surface of the substrate opposite the front surface.

The back layered structure may comprise first and second back layers, each comprising a percentage of crystalline material which is arranged within an amorphous matrix. The second back layer may be interposed between the first back layer and the back surface of the substrate. The percentage of crystalline material in the first back layer may be greater than the percentage of crystalline material in the second back layer.

The back layered structure may be configured in the same manner as the front layered structure, as defined in any of the preceding paragraphs. For example, each layer of the back layered structure may be formed of a material having a prescribed chemical composition. Each of the first and/or second back layers may be deposited (or e.g. diffused or implanted) on to the substrate. The first and/or second back layers may be at least partially, or substantially, formed of at least one of silicon sub-oxide and silicon carbide.

The back layered structure may comprise a third back layer and a passivation layer. The third back layer may be interposed between the back surface of the substrate and the first and second back layers. The passivation may be interposed between the third back layer and the back surface of the substrate.

The back passivation layer may be formed of amorphous silicon (a-Si), which may be configured to passivate the back surface of the substrate. The third layer may be at least partially, or substantially, formed of a concentration of crystalline material arranged within an amorphous matrix. The percentage of crystalline material in the third back layer may be less than the percentage of crystalline material in the second and/or first layer(s). The third back layer may be formed of silicon.

According to an illustrative embodiment, each of the layers in the front layered structure may be formed of at least one of silicon sub-oxide (SiOx) and silicon carbide (SiC). The layers each comprise crystalline regions of silicon sub-oxide (SiOx) and/or silicon carbide (SiC) arranged in an amorphous matrix of the same, and the front passivation layer is formed of amorphous silicon sub-oxide (SiOx) and/or silicon carbide (SiC).

Turning to the back layered structure, the first and second back layers may be formed of crystalline regions of silicon sub-oxide (SiOx) and/or silicon carbide (SiC) arranged in an amorphous matrix of the same, whereas the third back layer and the passivation layer may each be formed of silicon. The third back layer may comprise crystalline regions of silicon arranged in an amorphous matrix of the same, and the back passivation layer may be substantially comprised of amorphous silicon.

Each of the layers of the front layered structure may be configured with a positive or a negative conductivity type (p-type or n-type). Each of the layers of the back layered structure may be configured with the other of the positive and negative conductivity types (n-type or p-type). According to an exemplary arrangement, the layers of the front layered structure may be configured with a negative conductivity type (n-type). The layers of the back layered structure may be configured with a positive conductivity type (p-type). The substrate may be configured with a negative conductivity type (n-type).

The first back layer may be configured with a concentration of dopant atoms which is greater than that of the second and/or third back layers. The second back layer may be configured with a concentration of dopant atoms which is less than a dopant concentration of the first back layer and greater than that of the third back layer.

The third back layer may be configured with a concentration of dopant atoms which is less than the respective dopant concentrations of the first and/or second back layers. In this way, the first back layer defines a heavily doped layer, the second back layer defines an intermediately doped layer and the third back layer defines a lightly doped layer of the back layered structure.

In embodiments, the front surface(s) of the substrate may be textured to form a textured surface corresponding to an uneven surface or having uneven characteristics. In this instance, an amount of light incident on the substrate increases because of the textured surface of the substrate, and thus the efficiency of the solar cell may be improved.

The layered structure may further comprise an anti-reflection layer, or coating, arranged opposite the first layer. The anti-reflection layer may be arranged such that at least the first layer is interposed between the anti-reflection layer and the substrate. The anti-reflection layer may have a single-layered structure or a multi-layered structure. The anti-reflection layer may be formed of a transparent conductive oxide (TCO), such as indium tin oxide (ITO), or Transition Metal Oxide (TMO) which has been textured to provide an anti-reflective surface. The anti-reflection layer advantageously reduces the reflectance of light incident on the solar cell and increases selectivity of a predetermined wavelength band, thereby increasing the efficiency of the solar cell.

The anti-reflection layer may be arranged such that at least the first layer is interposed between the transparent conductive oxide coating and the substrate. The transparent conductive oxide coating may be electrically connected to first layer. The transparent conductive oxide coating may be configured to increase lateral carrier transport to an electrode arranged on the respective surface of the layered structure.

As described above, the solar cell may comprise an electrode arranged opposite the layered structure and configured to extract photo-generated charge carriers from the solar cell. The electrode may be arranged such that the layered structure is interposed between the electrode and the substrate.

When the layered structure is arranged on a back (e.g. backmost) surface of the substrate, the electrode may be arranged on a back surface of the layered structure, to define a back electrode of the solar cell.

When the layered structure is arranged on a front (e.g. frontmost) surface of the substrate, the electrode may be arranged on a front surface of the layered structure, to define a front electrode of the solar cell.

When the solar cell comprises a front layered structure and a back layered structure arranged on a front and back surface of the substrate, respectively, the solar cell may comprise a front electrode arranged on the front surface of the front layered structure and back electrode arranged on the back surface of the back layered structure. Each electrode may be configured to form an ohmic contact with the respective surfaces of the front and back layered structures.

The front and back electrodes may each comprise a plurality of finger electrodes which are arranged on the respective surfaces of the layered structures. Each finger electrode may be configured with an axial length which is substantially greater than its width. Both the width and axial length of the finger electrode may be measured in perpendicular directions in the plane of the respective surface of the layered structure. The finger electrodes may extend in a transverse direction which is parallel with the width direction of the layered structure.

The finger electrodes within each of the pluralities of front and/or back finger electrodes may be spaced apart across the respective surfaces to define transversely-extending spaces between the finger electrodes. The finger electrodes may be spaced apart in a longitudinal direction which is substantially parallel with the length direction of the layered structure. The finger electrodes in each plurality may be substantially parallel to one another. Accordingly, the plurality of back finger electrodes may form an array of parallel, longitudinally spaced (e.g. equally spaced) finger electrodes.

It will be understood that the terms ‘conductive’ and ‘insulating’ as used herein, are expressly intended to mean electrically conductive and electrically insulating, respectively. The meaning of these terms will be particularly apparent in view of the technical context of the disclosure, being that of photovoltaic solar cell devices. It will also be understood that the term ‘ohmic contact’ is intended to mean a non-rectifying electrical junction (i.e. a junction between two conductors which exhibits a substantially linear current—voltage (I-V) characteristic).

According to an exemplary arrangement, the solar cell may comprise a substrate, a front layered structure arranged on a front surface of the substrate and a back layered structure arranged on a back surface of the substrate. The front layered structure may define a front surface field (FSF), or accumulator, of the solar cell being configured to extract charge carriers from the substrate during operation of the solar cell. The accumulator may be electrically connected to a front electrode and arranged such that the accumulator is arranged between the front electrode and the substrate. The back layered structure may define an emitter being positioned opposite the substrate to form a p-n junction.

According to an alternative exemplary arrangement, the solar cell may comprise a substrate, a front layered structure arranged on a front surface of the substrate and a back layered structure arranged on a back surface of the substrate. The front layered structure may define an emitter of the solar cell, being positioned opposite the substrate to form a p-n junction. The emitter may be electrically connected to a front electrode and arranged such that the emitter is arranged between the front electrode and the substrate. The back layered structure may define a back surface field being positioned toward the back surface of the substrate, i.e. between the substrate layer and a back electrode. Accordingly, the back surface field may be configured to extract charge carriers from the substrate and transfer them to the back electrode during operation of the solar cell.

According to a second aspect there is provided a solar module comprising a plurality of solar cells according to the first aspect. The plurality of solar cells may be electrically coupled together.

According to a third aspect there is provided a method for manufacturing a solar cell according to the first aspect comprising: the method comprising providing a substrate (e.g. a silicon substrate) and arranging a layered structure on a surface of the substrate, the step of arranging the layered structure (e.g., on the silicon substrate) comprises arranging a first layer on the surface of the substrate and, prior to arranging the first layer, arranging a second layer between the first layer and the surface of the substrate such that it is interposed therebetween, the first and second layers each comprising a percentage of crystalline material arranged within an amorphous matrix; wherein the method comprises configuring the first layer with a percentage of crystalline material greater than the percentage of crystalline material in the second layer.

The method may comprise, prior to arranging the first and second layers, arranging a passivation layer and a third layer on the surface of the substrate. The third layer may comprise a percentage of crystalline material arranged within an amorphous matrix, and the passivation layer may be formed of an amorphous material.

The method may comprise, prior to arranging the third layer, arranging the passivation layer between the third layer and the surface of the substrate such that it is interposed therebetween.

The method may further comprises configuring the third layer with a percentage of crystalline material which is less than the percentage of crystalline material in the second layer.

The step of arranging the layered structure may comprise sequentially depositing the layers onto the surface of the substrate using a vapour deposition process. The vapour deposition process may be a plasma enhanced chemical vapour deposition process (PECVD). Advantageously, each of the layers of the layered structure may be deposited using the same deposition method as a part of a single continuous process.

The method may comprise controlling at least one parameter of the vapour deposition process to determine the structural, chemical and dopant composition of at least one of the layers of the layered structure. The vapour deposition process parameter may comprise a gas composition and/or a gas flow rate. The vapour deposition process parameter may define a temperature of the deposition chamber. The gas composition may comprise at least one of carbon dioxide (CO₂), silicon containing gas (e.g. silane SiH₄) and hydrogen (H₂).

The method may comprise configuring the structural composition of the layers of the layered structure so as to determine a concentration of crystalline material and/or amorphous material in each of the layers. The method may comprise configuring the structural composition so as to determine the size of the crystalline regions within at least one of the layers. The method may comprise controlling at least one of a CO₂ gas flow rate, a silicon containing gas (e.g. SiH₄) flow rate, a H₂ gas flow rate, a plasma power level, a plasma temperature and the temperature and/or pressure of the deposition chamber to determine the concentration of crystalline material in a layer of the layered structure.

The method may comprise controlling at least one parameter of the vapour deposition process to determine a chemical composition of at least one of the layers of the layered structure. The method may comprise configuring the chemical composition of the first layer with a first material comprising at least one of silicon, silicon sub-oxide (SiOx) and silicon carbide (SiC). The method may comprise configuring the chemical composition of the second layer with a second material comprising at least one of silicon, silicon sub-oxide (SiOx) and silicon carbide (SiC). The method may comprise configuring the chemical composition of the third layer with a third material comprising at least one of silicon, silicon sub-oxide (SiOx) and silicon carbide (SiC). It will be appreciated that the deposition parameters described above (e.g. the CO₂ gas flow rate, silicon containing gas flow rate, H₂ gas flow rate, plasma power level, plasma temperature and the temperature and/or pressure of the deposition chamber) may also be controlled in order to determine the chemical composition of each of the layers in the layered structure.

The method may comprise pre-treating the surface upon which at least one of the layers of the layered structure is to be deposited. The method of surface pre-treating may comprise etching the surface with hydrogen gas (H₂), which may be used, for example, to etch away silicon oxide from an exposed surface. The method may further comprise treating the surface with carbon dioxide (CO₂).

The method may further comprise post-annealing at least one of the layers of the layered structure prior to depositing the next sequential layer. The post-annealing step may be conducted when the layered structure is arranged within the same deposition chamber which is used to deposit the layers.

The method may comprise controlling at least one parameter of the vapour deposition process to determine a conductivity type of at least one of the intrinsic, third, second and first layers. The method may comprise configuring the conductivity type of the layers to be p-type or n-type. The method may comprise configuring at least one of the layers such that it is substantially undoped (i.e. intrinsic). Doping of the layers may be achieved by controlling the flow rate of a dopant gas into the deposition chamber. The dopant gas may comprise a boron containing gas, such as diborane (B₂H₆) or trimethylboron (B(CH₃)₃), for p-type doping and a phosphorus containing gas, such as phosphine (PH₃) for n-type doping. The flow rate of the dopant gas may be controlled relative to the flow rate of a silicon based gas being directed into the deposition chamber.

The method may comprise controlling at least one parameter of the vapour deposition process to determine a dopant concentration of at least one of the layers of the layered structure. The method may comprise doping the first layer with a first dopant concentration, doping the second layer with a second dopant concentration and doping the third layer with a third dopant concentration. The method of determining the first, second and third dopant concentrations may comprise controlling the flow rate of a dopant gas into the deposition chamber, as described above.

The method may further comprise arranging an electrode on the first layer of the layered structure. The layered structure may comprise a back (e.g. backmost) surface and a front (e.g. frontmost) surface being opposite the back surface. Accordingly, when the layered structure is arranged on the back surface of the substrate, the method may comprise arranging an electrode onto the back surface of the layered structure to define a back electrode. When the layered structure is arranged on the front surface of the substrate, the method may comprise arranging an electrode onto the front surface of the layered structure to define a front electrode.

The electrode may comprise a plurality of finger electrodes and so the method may comprise depositing a plurality of finger electrodes onto the first layer. The method may comprise depositing an electrically conductive material onto a front or back surface of the layered structure.

The electrically conductive material may be deposited by various methods including evaporation, plating, printing etc. For example, the electrically conductive material may comprise a printed material. The method of depositing the electrically conductive material may comprise printing a printable precursor of the printed material onto the surface of the layered structure. The method may further comprise curing the printable precursor according to a firing process to form the finger electrodes.

The method may comprise arranging at least an anti-reflection layer, or coating, and/or a transparent conductive oxide layer, or coating, between the first layer and the electrode. The method may comprise depositing the anti-reflection, and/or transparent conductive oxide, coating onto the first layer of the layered surface before depositing the electrode. The method of depositing the anti-reflection, and/or transparent conductive oxide, coating may comprise magnetron sputtering, or any other suitable deposition method.

The skilled person will appreciate that except where mutually exclusive, a feature or parameter described in relation to any one of the above aspects may be applied to any other aspect. Furthermore, except where mutually exclusive, any feature or parameter described herein may be applied to any aspect and/or combined with any other feature or parameter described herein.

### BRIEF DESCRIPTION OF THE DRAWINGS

Embodiments will now be described by way of example only, with reference to the Figures, in which:

FIG. 1 is a schematic illustrating the layers of a solar cell; and

FIG. 2 is a flow chart illustrating a method of forming the solar cell of FIG. 1.

### DETAILED DESCRIPTION

Aspects and embodiments of the present disclosure will now be discussed with reference to the accompanying figures. Further aspects and embodiments will be apparent to those skilled in the art.

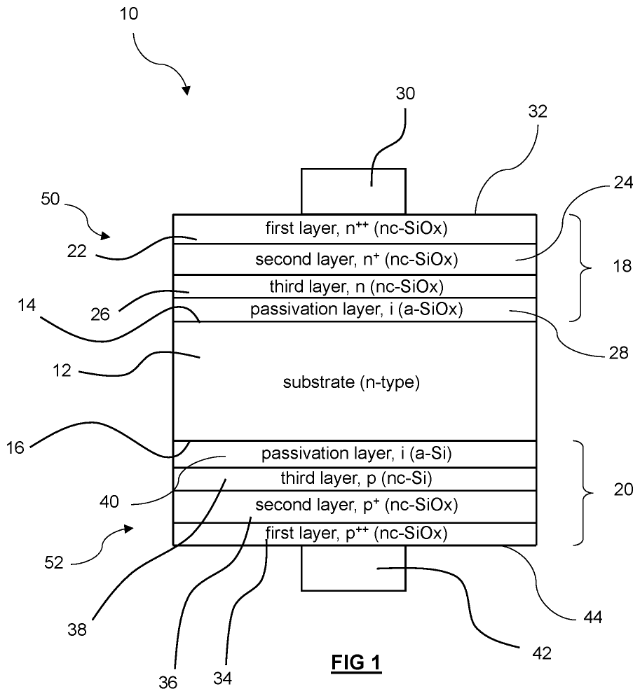

FIG. 1 schematically illustrates a solar cell 10 comprising, among other layers, a semiconductor substrate 12 comprising a first (i.e. front) surface 14, upon which light from a radiative source (e.g. the sun) is incident during normal use, and a second (i.e. back) surface 16 that is opposite the front surface 14. That is, the front surface 14 may be configured in use to face the sun, whereas the back surface 16 may be configured in use to face away from the sun. In the present embodiment, the substrate 12 is a crystalline silicon substrate.

However, it is to be understood that in some alternative embodiments, the substrate 12 may be formed from a semiconductor material other than silicon.

The substrate 12 divides the solar cell 10 into a front portion 18 that is forward (i.e. in front of) of the substrate 12, and a back portion 20 that is rearward of the substrate 12. Light incident on the solar cell 10 passes through the front portion 18, the substrate 12 and then the back portion 20.

The solar cell 10 is a back emitter solar cell (and, in particular, a back emitter heterojunction solar cell 10). As such the solar cell 10 is provided with a front surface field 50, or accumulator 50, and an emitter 52 arranged either side of the substrate 12. Accordingly, the accumulator 50 forms part of the front portion 18 and the emitter 52 forms part of the back portion 20. According to the illustrated embodiment, the substrate 12 is an n-type monocrystalline silicon wafer which forms a p-n junction with the p-type rear emitter 52.

Each of the front and back portions 18, 20 comprises a plurality of layers which are arranged to define separate layered structures. The front portion 18 (also referred to herein as a front layered structure 18) is arranged opposite the front surface 14 of the substrate 12 and the back portion 20 (also referred to herein as a back layered structure 20) is arranged opposite the back surface 16 of the substrate 12. The constituent layers of the front and back layered structures 18, 20 are sequentially deposited (or e.g. diffused or implanted) onto the respective front and back surfaces 14, 16 of the substrate 12.

Each of the layers of the front and back portions 18, 20 are configured with a width, a length and a depth. The width and length of each layer is measured in perpendicular directions that are aligned with the front and back surfaces 14, 16 of the substrate 12. For each layer, its width and length is substantially greater than its depth, which is measured in a direction that is perpendicular to the front and back surfaces 14, 16 of the substrate 12.

The solar cell 10 is further provided with a front electrode 30, arranged at a front surface 32 of the accumulator 50. A transparent conductive oxide (TCO) layer (not shown), also referred to as a front TCO, is also provided at the front surface 32 and sandwiched therebetween. A back electrode 42 is arranged at a back surface 44 of the emitter 52 and a further TCO layer (not shown), also referred to as a back TCO, is provided at the back surface 44, interposed between the back electrode 42 and the emitter 52. The front and back TCO are formed of indium tin oxide (ITO) and the front and back electrodes 30, 42 are formed of silver.

The front portion 18 of the solar cell 10 comprises, in order moving towards the substrate 12, a first front layer 22, a second front layer 24, a third front layer 26 and a front passivation layer 28. The first, second and third front layers 22, 24, 26 are all n-type and together they define the accumulator 50 of the solar cell 10.

The first, second and third front layers 22, 24, 26 have depths of 3 nm, 7 nm and 2 nm, respectively (as measured in the vertical direction shown in FIG. 1). The passivation layer 28 is interposed between the accumulator 50 and the front surface 14 of the substrate 12. It has a depth of 3 nm (as measured in the vertical direction shown in FIG. 1).

The first, second and third front layers 22, 24, 26 all have different structural compositions. They each comprise regions of crystalline material arranged within an amorphous matrix (i.e. to define a crystalline material). However, the first layer 22 has a percentage of the crystalline material which is greater than that of the second and third layers 24, 26. The second layer 24 has a percentage of crystalline material which is greater than that of the third layer 26, but less than that of the first layer 22. The third layer 26 has percentage of crystalline material which is less than both the first and second layers 22, 24. The front passivation layer 28 is formed of amorphous material.

Each of the first, second and third front layers 22, 24, 26 are formed of nanocrystalline silicon sub-oxide (nc-SiOx). The passivation layer 28 is formed of amorphous silicon sub-oxide (a SiOx).

As described above, each of the first, second and third layers 22, 24, 26 are configured such that they have n-type conductivity which is determined by the inclusion of dopant atoms in each of the respective materials. However, each of the layers is configured with a different dopant concentration. The first front layer 22 has a dopant concentration which is greater than that of the second and third layers. The second front layer 24 has a dopant concentration which is less than that of the first front layer and greater than that of the third front layer. Finally, the third front layer 26 has a dopant concentration which is less than that of both the first and second layers 22, 24. In this way, the first front layer 22 defines a heavily doped accumulator layer (n++), the second front layer 24 defines an intermediately doped accumulator layer (n+) and the third front layer 26 defines a lightly doped accumulator layer (n) of the solar cell 10.

The gradual increase in doping concentration from third front layer 26 to the first front layer 22 increases the passivation of the front surface 14 of the substrate 12 by the lightly doped third front layer 26. The high doping concentration in the first front layer 22 also ensures a good ohmic contact between the accumulator 50 and the front electrode 30.

The back portion 20 of the solar cell 10 comprises, in order moving towards the substrate 12, a first, second and third back layer 34, 36, 38, which together define the emitter 52 of the solar cell 10. A back passivation layer 40 of the solar cell 10 is interposed between the emitter 52 and the back surface 16 of the substrate 12.

Similar to the front passivation layer 28, the back passivation layer 40 has a depth of 3 nm, and the first, second and third back layers 34, 36, 38 have depths of 3 nm, 7 nm and 2 nm, respectively.

As with the front layered structure 18, the first, second and third back layers 34, 36, 38 each comprise regions of crystalline material arranged within an amorphous matrix (i.e. to define a crystalline material). Similarly, the first layer 34 has a percentage of the crystalline material which is greater than that of the second and third layers 36, 38. The second layer 36 has a percentage of crystalline material which is greater than that of the third layer 38, but less than that of the first layer 34. The third layer 38 has a percentage of crystalline material which is less than both the first and second layers 34, 36. The back passivation layer 40 is formed of amorphous material.

The first and second back layers 34, 36 are formed of nanocrystalline silicon sub-oxide (nc-SiOx). However, in contrast to the front layered structure 18 the third back layer and the back passivation layer 40 are each formed of substantially pure silicon (Si).

Each of the first, second and third back layers 34, 36, 38 are configured such that they have p-type conductivity which is determined by the inclusion of dopant atoms in each of the respective materials. However, each of the layers is configured with a different dopant concentration. The first layer 34 has a dopant concentration which is greater than that of the second and third layers. The second layer 36 has a dopant concentration which is less than that of the first layer 34 and greater than that of the third layer 38. Finally, the third layer 38 has a dopant concentration which is less than that of both the first and second layers 34, 36. In this way, the first back layer 34 defines a heavily doped emitter layer (p++), the second back layer 36 defines an intermediately doped emitter layer (p+) and the third back layer 38 defines a lightly doped emitter layer (p) of the solar cell 10.

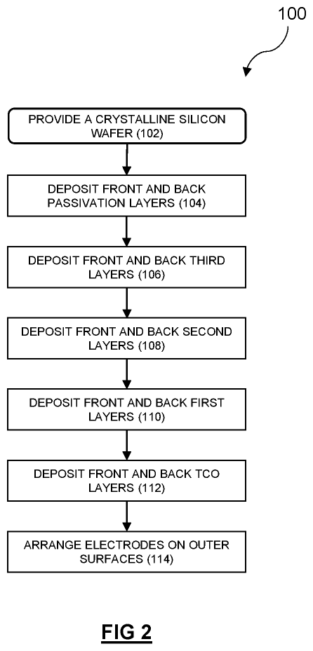

FIG. 2 depicts a method 100 of forming a solar cell, such as those described above. The method comprises a first step 102 of providing a crystalline silicon wafer to define the substrate 12 of the solar cell 10. In a second method step 104, the method comprises depositing the front and back passivation layers 28, 40 onto the front and back surfaces 14, 16 of the substrate 12, respectively. A third method step 106 comprises depositing the front and back third layers 26, 38 onto the front and back passivation layers 28, 40, respectively. In a fourth step 108, the method comprises depositing the front and back second layers 24, 36 onto the third layers 26, 38, respectively. In a fifth step 110, the method comprises depositing the front and back first layers 22, 34 onto the second layers 24, 36, respectively.

The second to fifth method steps 102, 104, 106, 108, 110 involve arranging (or forming) layers on the front and rear surfaces 14, 16 of the silicon wafer substrate 12. This may comprise e.g. depositing, diffusing, doping and/or implantation steps. The layers referred to are those forming the front and rear portions 18, 20 of the solar cell 10 described above (e.g. emitter, accumulator and passivation layers etc.).

In particular, method steps three to five 106, 108, 110 involve forming the doped semiconductor layers of the accumulator and emitter 50, 52, as defined above. Each of these steps involves depositing and doping a corresponding semiconductor material using a vapour deposition process (e.g. PECVD). In general, the parameters of the vapour deposition process are configured to determine the composition (e.g. structural and/or chemical) and also the dopant concentration of each layer.

A sixth method step 112, comprises depositing front and back TCO layers onto the front and back surfaces 32, 44 of the accumulator 50 and emitter 52, respectively. Finally, a seventh method step 114 comprises arranging front and back electrodes 30, 42 on the outermost surfaces of the front and back portions 18, 20 of the solar cell 10.

It will be appreciated that the steps of forming the front and back layers are not limited to the method as described. For example, at least one or each of the front layers can be deposited before the deposition at least one or each of the rear layers, or vice versa, depending on the design of the vapour deposition apparatus.

It will be understood that the invention is not limited to the embodiments above-described and various modifications and improvements can be made without departing from the concepts described herein. Except where mutually exclusive, any of the features may be employed separately or in combination with any other features and the disclosure extends to and includes all combinations and sub-combinations of one or more features described herein.

1. A solar cell comprising a silicon substrate and a layered structure arranged on a surface of the silicon substrate, the layered structure comprising;
a first layer comprising a percentage of crystalline material arranged within an amorphous matrix, the first layer being arranged on the surface of the silicon substrate;
a second layer comprising a percentage of crystalline material arranged within an amorphous matrix, the second layer being interposed between the first layer and the surface of the silicon substrate;
wherein the percentage of crystalline material in the first layer is greater than the percentage of crystalline material in the second layer.

2. The solar cell according to claim 1, wherein the first layer is arranged directly on the second layer.

3. The solar cell according to claim 1, wherein the percentage of crystalline material in the first layer is between 75% and 100%, and percentage of crystalline material in the second crystalline material is between 50% and 75%.

4. The solar cell according to claim 1, wherein the crystalline material of the first and second layers comprises a plurality of crystalline regions arranged within an amorphous matrix.

5. The solar cell according to claim 4, wherein a largest dimension of each of the plurality of crystalline regions is less than 15 nm.

6. The solar cell according to claim 1, wherein the amorphous matrix is formed of a material having substantially the same chemical composition as the crystalline material.

7. The solar cell according to claim 1, wherein the crystalline material of the first layer is at least partially formed of at least one of silicon sub-oxide (SiOx) and silicon carbide (SiC).

8. The solar cell according to claim 1, wherein the crystalline material of the second layer is at least partially formed of at least one of silicon sub-oxide (SiOx) and silicon carbide (SiC).

9. The solar cell according to claim 7, wherein the layered structure is arranged on a front surface of the silicon substrate which is configured to face a radiative source, when the solar cell is in use.

10. The solar cell according to claim 1, wherein the first and second layers comprise a combined depth of less than 15 nm, optionally less than 11 nm.

11. The solar cell according to claim 1, wherein the layered structure comprises:
a third layer comprising a percentage of crystalline material arranged within an amorphous matrix, the third layer being interposed between the second layer and the surface of the silicon substrate; and
a passivation layer formed of amorphous material, the passivation layer being interposed between the third layer and the surface of the silicon substrate.

12. The solar cell according to claim 11, wherein the percentage of crystalline material in the third layer is less than the percentage of crystalline material in the second layer.

13. The solar cell according to claim 11, wherein the third layer comprises a depth of less than 5 nm, preferably less than 4 nm, and at least 1 nm, and wherein the passivation layer comprises a depth of less than 3 nm.

14. The solar cell according to claim 1, wherein the crystalline material in at least one of the layers of the layered structure is substantially evenly distributed across the depth of the respective layer.

15. The solar cell according to claim 1, wherein the first and second layers are configured with a conductivity type determined by the inclusion of dopant atoms, the first layer having a first concentration of dopant atoms and the second layer having a second concentration of dopant atoms which is less than the first concentration.

16. The solar cell according to claim 11, wherein the third layer is configured with a conductivity type determined by the inclusion of dopant atoms, the third layer having a concentration of dopant atoms which is less than the concentration of dopant atoms in the second layer.

17. The solar cell according to claim 1, wherein the layered structure defines a front layered structure arranged on a front surface of the silicon substrate, and the first and second layers define a first and second front layers, respectively, wherein the solar cell further comprises a back layered structure arranged on a back surface of the silicon substrate opposite the front surface;
wherein the back layered structure comprises first and second back layers, each comprising a percentage of crystalline material arranged within an amorphous matrix, the second back layer is interposed between the first back layer and the back surface of the silicon substrate;
wherein the percentage of crystalline material in the first back layer is greater than the percentage of crystalline material in the second back layer.

18. The solar cell according to claim 17, wherein at least one of the layers of the front layered structure are configured with a conductivity type, which is the opposite conductivity type to that of at least one of the layers of the back layered structure.

19. The solar cell according to claim 17, wherein the silicon substrate is configured with a negative conductivity type, at least one of the layers of the front layered structure is configured with a positive conductivity type, and at least one of the layers of the back layered structure is configured with a negative conductivity type.

20. A solar module comprising a plurality of solar cells according to claim 1, wherein the plurality of solar cells are electrically coupled together.

21. A method for manufacturing a solar cell comprising a layered structure, the method comprising providing a silicon substrate and arranging a layered structure on a surface of the silicon substrate, the layered structure comprising a first layer and a second layer each comprising a percentage of crystalline material arranged within an amorphous matrix, the step of arranging the layered structure comprises;
arranging the second layer on the surface of the silicon substrate; and,
arranging the first layer on the second layer such that the second layer is interposed between the first layer and the surface of the silicon substrate;
wherein the method of arranging the first and second layers comprises configuring the first layer with a percentage of crystalline material greater than the percentage of crystalline material in the second layer.

22. The method according to claim 21, wherein the layered structure comprises a third layer comprising a percentage of crystalline material arranged within an amorphous matrix and a passivation layer formed of amorphous material, the method comprises, prior to arranging the first and second layers;
arranging the passivation layer on the surface of the silicon substrate; and
arranging the third layer on the passivation layer.

23. The method according to claim 22, wherein the method comprises configuring the third layer with a percentage of crystalline material which is less than the percentage of crystalline material in the second layer.

24. The method according to claim 21, wherein the step of arranging the layered structure comprises sequentially depositing the layers of the layered structure onto the surface of the silicon substrate using a vapour deposition process.

25. The method according to claim 24, wherein the method comprises controlling at least one parameter of the vapour deposition process to determine the percentage of crystalline material in the first and second layers, wherein the at least one parameter comprises at least one of a gas composition, a gas flow-rate, a plasma power level, a plasma temperature, a temperature and pressure of the deposition chamber.
